(19) United States
(12) Patent Application Publication
(10) Pub. No.: US 2023/0060729 A1
(43) Pub. Date: Mar. 2, 2023

(54) POWER DEVICE AND POWER MODULE

(71) Applicant: DELTA ELECTRONICS, INC., Taoyuan City (TW)

(72) Inventors: Chia-Chi WU, Taoyuan City (TW); Lian-An JIAN, Taoyuan City (TW); Cheng-Yu SHEN, Taoyuan City (TW); Chun-Hong CHEN, Taoyuan City (TW); Hung-Hsiao LIU, Taoyuan City (TW)

(21) Appl. No.: 17/823,515

(22) Filed: Aug. 30, 2022

(30) Foreign Application Priority Data
Aug. 31, 2021 (CN) 202122078251.X

(51) Int. Cl. H01L 23/40; H01L 23/367

(52) U.S. Cl. CPC H01L 23/4006; H01L 23/367; H01L 2023/4043; H01L 2023/4087

(57) ABSTRACT

The present disclosure is related to a power module. The power module includes first fasteners and power devices. The power devices are adjacently disposed and locked by the first fasteners. Each of the power devices packages a power electronic therein. Each of the power devices includes a first extending portion. The first extending portion extends from a side of the power device. The first extending portion includes at least one first curved opening for receiving the first fastener. The first curved openings are adjacently disposed to form a first inserting hole. The first fastener passes through the first inserting hole.

### RELATED APPLICATION

This application claims priority to China Application Serial Number 202122078251.X, filed Aug. 31, 2021, which is herein incorporated by reference in its entirety.

### BACKGROUND

### Field of Invention

The present disclosure relates to a power device and a power module.

### Description of Related Art

In general, when two power devices are abutted to each other, they need to be fixed by clips. The clips may provide a positioning effect to align the adjacent power devices. The clips may have inserting holes such that screws may pass through the inserting holes of the clips to lock the clips and the power devices. However, a downforce generated while locking the clips may force the power devices to tilt, resulting in insufficient structural stability for the power devices.

### SUMMARY

An aspect of the present disclosure is related to a power device.

According to one embodiment of the present disclosure, a power device includes a main body portion and a first extending portion. The first extending portion extends from a first side of the main body portion. The first extending portion has a first curved opening. The first curved opening is used to receive a first fastener. The first fastener passes through the first curved opening to be locked. The main body portion and the first extending portion are formed in a stepped structure.

In one embodiment of the present disclosure, the first extending portion is elongated, the first extending portion is adjacent to the first side of the main body portion, and the first curved opening is near one end of the first extending portion.

In one embodiment of the present disclosure, the first extending portion is elongated, the first extending portion is adjacent to the first side of the main body portion, and the first curved opening is disposed in a middle of the first extending portion.

In one embodiment of the present disclosure, the power device further includes a second extending portion. The second extending portion extends from a second side opposite to the first side of the main body portion. The second extending portion has a second curved opening for receiving a second fastener. The second fastener passes through the second curved opening to be locked. The main body portion and the second extending portion are formed in a stepped structure. The first curved opening and the second curved opening face opposite directions. The second curved opening of the second extending portion is symmetrically disposed with the first curved opening of the first extending portion

In one embodiment of the present disclosure, the power device further includes a housing and a sealing tape. The housing has an accommodating space. The sealing tape is located in the accommodating space of the housing. The sealing tape is located below the first extending portion and the second extending portion.

In one embodiment of the present disclosure, an inserting hole is formed by the second curved opening of the second extending portion and a curved opening of a first protruding rib of the housing.

In one embodiment of the present disclosure, the housing has a second protruding rib opposite to the first protruding rib, and a curved opening of the second protruding rib corresponds to the first curved opening of the first extending portion.

Another aspect of the present disclosure is related to a power module.

According to one embodiment of the present disclosure, a power module includes a plurality of first fasteners and a plurality of power devices. The power devices are disposed adjacently and locked by the first fasteners. Each of the power devices packages a power electronic therein. Each of the power devices includes a first extending portion. Each of the first extending portions extends from a side of each of the power devices. Each of the first extending portions includes at least one first curved opening for receiving one of the first fasteners. Two of the first curved openings are disposed to each other and form a first inserting hole. One of the first fasteners passes through the first inserting hole.

In one embodiment of the present disclosure, the power devices are a first power device and a second power device adjacent to each other, and a top of one of the first fasteners is lower than a top of the first power device and a top of the second power device.

In one embodiment of the present disclosure, the power module further includes a housing and a second fastener. The housing carries the power devices. A bottom of one of the first fasteners is fixed in the housing. The second fastener passes through a second inserting hole and has a bottom fixed in the housing. The second inserting hole is located at a second extending portion of one of the power devices.

In one embodiment of the present disclosure, the housing includes a protruding rib. The protruding rib is adjacent to the second extending portion. A second curved opening of the second extending portion corresponds to a curved opening of the protruding rib to form the second inserting hole. The second fastener is locked to the second extending portion and the protruding rib of the housing.

In one embodiment of the present disclosure, the protruding rib of the housing is coplanar with the second extending portion.

In one embodiment of the present disclosure, the power module further includes sealing tapes. The sealing tapes are located in accommodating spaces of the housing, respectively. One of the power devices covers one of the accommodating spaces, and the sealing tapes are located below the power devices.

In one embodiment of the present disclosure, the first fasteners are located between adjacent two of the sealing tapes.

According to one embodiment of the present disclosure, a power module includes a housing, a plurality of fasteners and a plurality of power devices. The housing has two protruding ribs opposite to each other. The fasteners are fixed in the housing. The power devices are located between the two protruding ribs of the housing. The power devices are adjacently arranged along a length direction of the housing and disposed in the housing. Two of the power devices are adjacent to the two protruding ribs, respectively. Each of the power devices includes two extending portions opposite to each other. First inserting holes are formed by curved openings of the extending portions of two adjacent power devices. Second inserting holes are formed by curved openings of the extending portions of said two of the power devices and curved openings of the two protruding ribs of the housing. The power devices are locked by the fasteners through the first inserting holes and the second inserting holes.

In one embodiment of the present disclosure, the power module further includes sealing tapes. The sealing tapes are located in accommodating spaces of the housing, respectively. The power devices cover the accommodating spaces. The sealing tapes are located below the power devices.

In one embodiment of the present disclosure, the fasteners are located between adjacent two of the sealing tapes.

In one embodiment of the present disclosure, one of the two protruding ribs of the housing is coplanar with one of the extending portions of said two of the power devices.

In the embodiments of the present disclosure, the first curved openings of the adjacent power devices of the power module form the first inserting hole, so the first fastener may be directly locked to the first extending portions of the power devices through the first inserting hole. Compared with the conventional power module, the first fastener of the power module may be directly locked to the first extending portions of the power devices, and the power module does not need a clip to locate the position between the two adjacent power devices, which may save cost and assembly time. In addition, the first fastener may be directly locked to the first extending portions of the power devices, which may provide an average downward force to avoid tilting the first fastener while fastening the power devices and may improve the structural stability of the power module.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of a power device according to one embodiment of the present disclosure.

FIG. 2 illustrates a stereoscopic view of the power device of FIG. 1.

FIG. 3 illustrates a stereoscopic view of a power module according to one embodiment of the present disclosure.

FIG. 4 illustrates a top view of the power module of FIG. 3, in which first fasteners and second fasteners are omitted.

FIG. 5 illustrates a top view of the power module of FIG. 4, in which a first power device, a second power device and a third power device are omitted.

FIG. 6 illustrates a cross-sectional view of the power module of FIG. 3 along a line segment A-A.

FIG. 7 illustrates an enlarged view of the first fasteners of FIG. 6.

FIG. 8 illustrates an enlarged view of the second fasteners of FIG. 6.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” “front,” “back” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

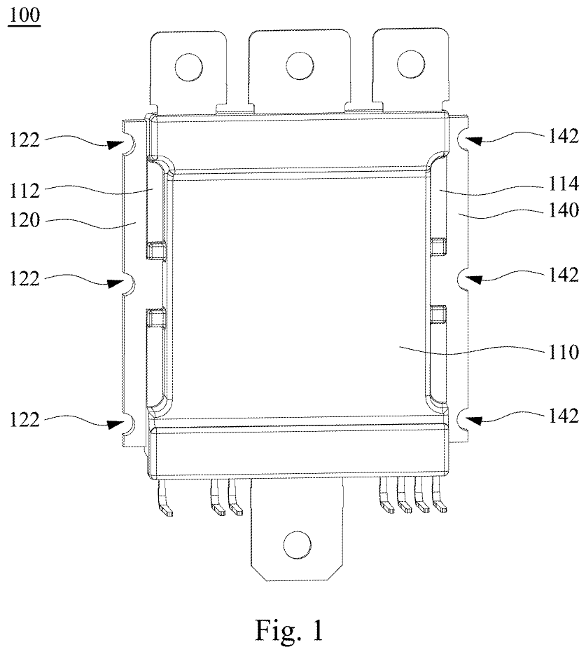

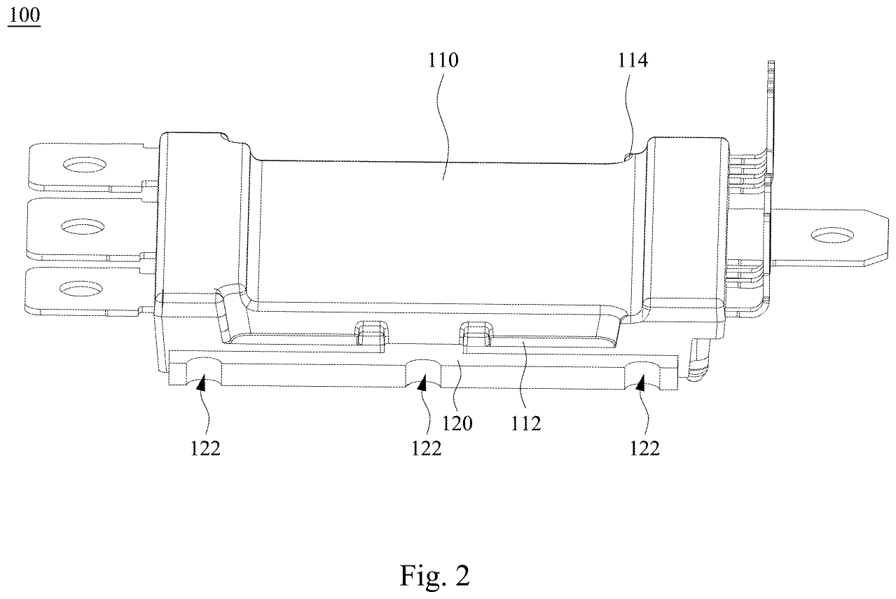

FIG. 1 illustrates a top view of a power device 100 according to one embodiment of the present disclosure. FIG. 2 illustrates a stereoscopic view of the power device 100 of FIG. 1. Referring to both FIG. 1 and FIG. 2, the power device 100 includes a main body portion 110 and a first extending portion 120. The first extending portion 120 of the power device 100 extends from a first side 112 of the main body portion 110. A height of the main body portion 110 is located above the first extending portion 120, and the main body portion 110 and the first extending portion 120 are adjacent to each other to form in a stepped structure.

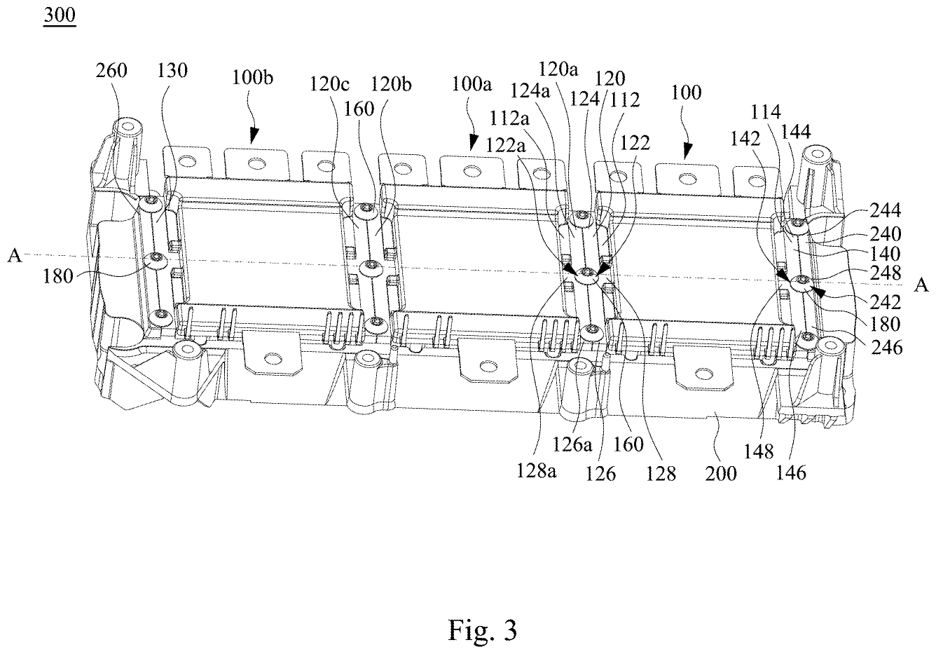

The first extending portion 120 has first curved openings 122. The first curved openings 122 of the first extending portion 120 are used to receive first fasteners 160 (will be described in FIG. 3), and the first fasteners 160 may pass through the first curved openings 122 to be locked. In this embodiment, the first extending portion 120 is elongated, and the first extending portion 120 is adjacent to the first side 112 of the main body portion 110. The first curved openings 122 of the first extending portion 120 may be disposed in a middle of the first extending portion 120, or disposed at one end near to the first extending portion 120. For example, the first extending portion 120 may have the first curved openings 122, and the three first curved openings 122 may be located at a first end, a middle position, and a second end opposite to the first end of the first extending portion 120, respectively.

In addition, the power device 100 further includes a second extending portion 140. The second extending portion 140 of the power device 100 extends from a second side 114 of the main body portion 110, and the second side 114 is opposite to the first side 112. The second extending portion 140 of the power device 100 has second curved openings 142. The second curved openings 142 of the second extending portion 140 are used to receive second fasteners 180 (will be described in FIG. 3), and the second fasteners 180 may pass through the second curved openings 142 to be locked. The main body portion 110 and the second extending portion 140 may form in a stepped structure, and the second extending portion 140 is adjacent to the second side 114 of the main body portion 110.

In this embodiment, the first curved openings 122 of the first extending portion 120 and the second curved openings 142 of the second extending portion 140 face opposite directions and are symmetrically disposed. The second curved openings 142 of the second extending portion 140 may be disposed in a middle of the second extending portion 140 or disposed at one end near to the second extending portion 140. For example, the second extending portion 140 may be elongated and has the second curved openings 142. The three second curved openings 142 may be located at a first end, a middle position and a second end opposite to the first end of the second extending portion 140, respectively.

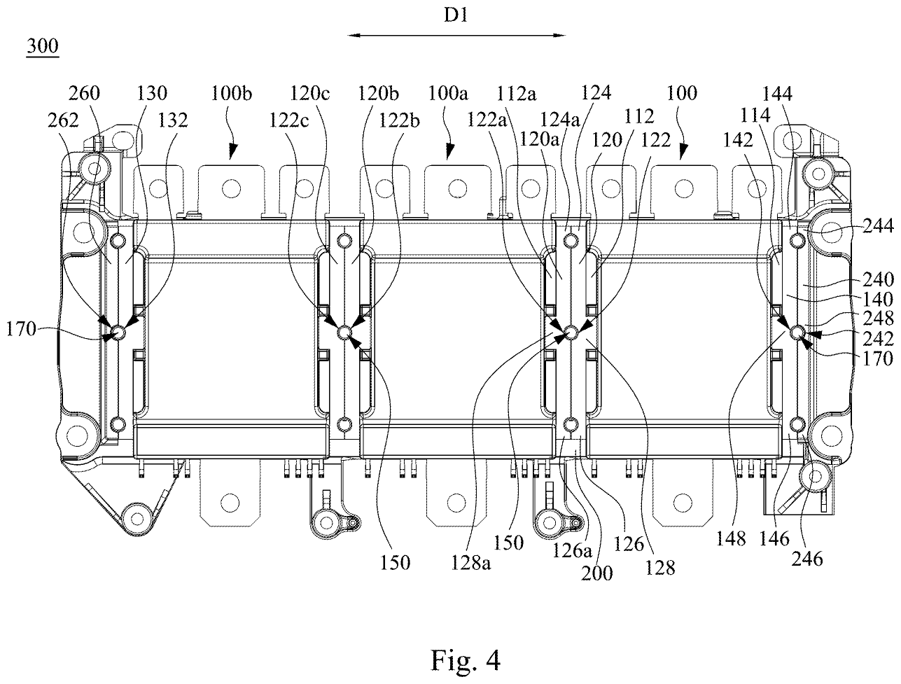

FIG. 3 illustrates a stereoscopic view of a power module 300 according to one embodiment of the present disclosure. FIG. 4 illustrates a top view of the power module 300 of FIG. 3, in which the first fasteners 160 and the second fasteners 180 are omitted. Referring to both FIG. 3 and FIG. 4, the power module 300 includes the power device 100, a power device 100a, a power device 100b, a plurality of the first fasteners 160 and a housing 200. The power device 100 of the power module 300 may be the first power device 100 adjacent to a first protruding rib 240 of the housing 200. The power device 100a of the power module 300 may be the second power device 100a. The power device 100b of the power module 300 may be the third power device 100b adjacent to a second protruding rib 260 of the housing 200. The first power device 100, the second power device 100a and the third power device 100b are located between the first protruding rib 240 and the second protruding rib 260. The first power device 100, the second power device 100a and the third power device 100b are adjacently arranged along a length direction D1 of the housing 200 and disposed in the housing 200. The first protruding rib 240 is opposite to the second protruding rib 260. The second power device 100a is located between the first power device 100 and the third power device 100b.

The first power device 100, the second power device 100a and the third power device 100b are locked by the first fasteners 160. Each of the first power device 100, the second power device 100a and the third power device 100b packages a power electronic therein. The first power device 100 includes the first extending portion 120 and the seconding extending portion 140 opposite to the first extending portion 120. The second power device 100a includes a first extending portion 120a and a first extending portion 120b opposite to the first extending portion 120a. The third power device 100b includes a first extending portion 120c and a second extending portion 130 opposite to the first extending portion 120c.

The first extending portion 120 of the first power device 100 extends from the first side 112 of the first power device 100, and the first extending portion 120a of the second power device 100a extends from a first side 112a of the second power device 100a. The first extending portion 120 of the first power device 100 includes the first curved openings 122, and the first extending portion 120a of the second power device 100a includes first curved openings 122a. The first curved openings 122 and the first curved openings 122a are used to receive the first fasteners 160. The first fasteners 160 are fixed in the housing 200. The first curved openings 122 and the first curved openings 122a are adjacent to each other to form first inserting holes 150, and the first fasteners 160 pass through the first inserting holes 150.

In some embodiments, the first inserting holes 150 are formed by the first curved openings 122 and the first curved openings 122a adjacent to the first curved openings 122. Moreover, the first inserting holes 150 are formed by first curved openings 122b of the first extending portion 120b and first curved openings 122c of the first extending portion 120c adjacent to the first curved openings 122b. In some embodiments, second inserting holes 170 are formed by the second curved openings 142 of the second extending portion 140 of the first power device 100 and curved openings 242 of the first protruding rib 240 of the housing 200. Moreover, the second inserting holes 170 are formed by second curved openings 132 of the second extending portion 130 of the third power device 100b and curved openings 262 of the second protruding rib 260 of the housing 200. The curved openings 262 of the second protruding rib 260 of the housing 200 correspond to the first curved openings 122 of the first extending portion 120 along the length direction D1 of the housing 200.

To be more specific, the first curved openings 122 and the first curved openings 122a of the power module 300 are adjacent to form the first inserting holes 150, so the first fasteners 160 may be directly locked to the first extending portion 120 and the first extending portion 120a through the first inserting holes 150. Compared with the conventional power module, the first fasteners 160 of the power module 300 may be directly locked to the first extending portion 120 of the first power device 100 and the first extending portion 120a of the second power device 100a, and the power module 300 does not need clips to locate the position between the first power device 100 and the second power device 100a and the position between the second power device 100a and the third power device 100b, which may save cost and assembly time. In addition, the first fasteners 160 may be directly locked to the first extending portion 120 of the first power device 100, the first extending portion 120a of the second power device 100a, the first extending portion 120b of the second power device 100a and the first extending portion 120c of the third power device 100b, which may provide an average downward force to avoid tilting the first fasteners 160 while fastening the first power device 100, the second power device 100a and the third power device 100b and may improve the structural stability of the power module 300.

The housing 200 of the power module 300 includes the first protruding rib 240 and the second protruding rib 260 opposite to the first protruding rib 240. The second extending portion 140 of the first power device 100 of the power module 300 is adjacent to the first protruding rib 240. The second extending portion 140 of the first power device 100 has the second curved openings 142. The first protruding rib 240 of the housing 200 has the curved openings 242. The second curved openings 142 of the second extending portion 140 correspond to the curved openings 242 of the first protruding rib 240 to form second inserting holes 170.

In this embodiment, the first inserting holes 150 formed by the first curved openings 122 and the first curved openings 122a and the second inserting holes 170 formed by the second curved openings 142 and the curved openings 242 are aligned along the length direction D1 of the housing 200. The first inserting holes 150 may be located at a middle position 128 of the first extending portion 120 of the first power device 100 and a middle position 128a of the first extending portion 120a of the second power device 100a. The first inserting holes 150 may be located at one end 124 of the first extending portion 120 and one end 124a of the first extending portion 120a. The first inserting holes 150 may be located at one end 126 of the first extending portion 120 and one end 126a of the first extending portion 120a. The second inserting holes 170 may be located at a middle position 148 of the second extending portion 140 of the first power device 100 and a middle position 248 of the first protruding rib 240 of the housing 200. The second inserting holes 170 may be located at one end 144 of the second extending portion 140 and one end 244 of the first protruding rib 240. The second inserting holes 170 may be located at one end 146 of the second extending portion 140 and one end 246 of the first protruding rib 240.

The power module 300 further includes the second fasteners 180. The second fasteners 180 of the power module 300 pass through the second inserting holes 170 and are directly locked to the second extending portion 130 of the third power device 100b, the second extending portion 140 of the first power device 100, the first protruding rib 240 and the second protruding rib 260. The first fasteners 160 and the second fasteners 180 may be disposed symmetrically and aligned along the length direction D1 of the housing 200. The first fasteners 160 may be located at the middle position 128 of the first extending portion 120 and the middle position 128a of the first extending portion 120a. The first fasteners 160 may be located at the end 124 of the first extending portion 120 and the end 124a of the first extending portion 120a. The first fasteners 160 may be located at the end 126 of the first extending portion 120 and the end 126a of the first extending portion 120a. The second fasteners 180 may be located at the middle position 148 of the second extending portion 140 and the middle position 248 of the first protruding rib 240. The second fasteners 180 may be located at the end 144 of the second extending portion 140 and the end 244 of the first protruding rib 240. The second fasteners 180 may be located at the end 146 of the second extending portion 140 and the end 246 of the first protruding rib 240. In this embodiment, the power module 300 has the six first fasteners 160 and the six second fasteners 180, but the number of the first fasteners 160 and the second fasteners 180 is not limited in this regard.

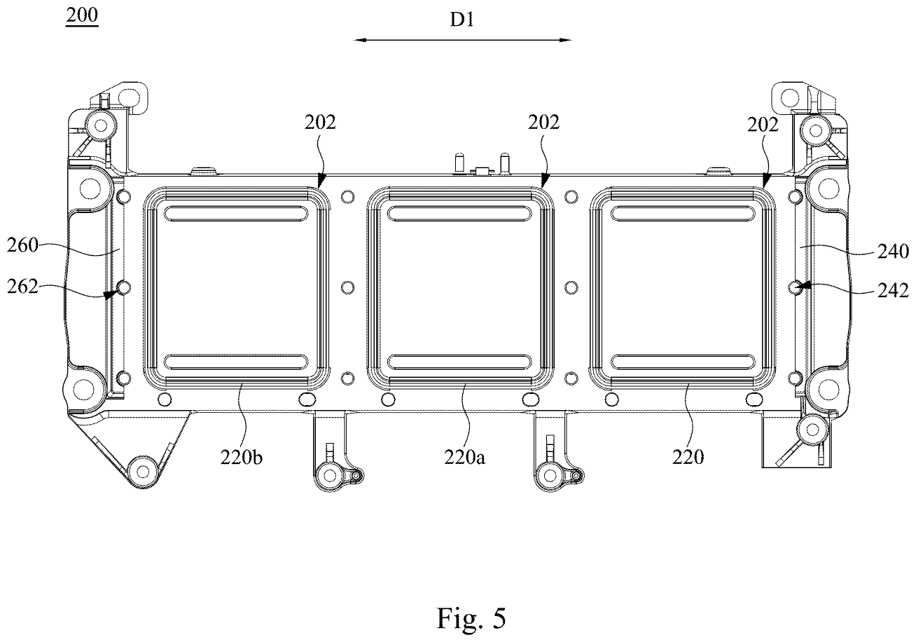

FIG. 5 illustrates a top view of the power module 300 of FIG. 4, in which the first power device 100, the second power device 100a and the third power device are omitted. Referring to both FIG. 4 and FIG. 5, the housing 200 has accommodating spaces 202. The first power device 100, the second power device 100a and the third power device 100b cover the accommodating spaces 202 of the housing 200. In addition, the power module 300 further includes a first sealing tape 220, a second sealing tape 220a and a third sealing tape 220b located in the accommodating spaces 202, respectively. The first sealing tape 220 is located below a bottom surface of the first power device 100. The second sealing tape 220a is located below a bottom surface of the second power device 100a. In addition, the third sealing tape 220b is located below the first extending portion 120c and the second extending portion 130 of the third power device 100b. When cooling liquid is filled in the accommodating spaces 202 of the housing 200, the first sealing tape 220, the second sealing tape 220a and the third sealing tape 220b may provide a sealing effect such that the cooling liquid below the first power device 100, the second power device 100a and the third power device 100b may not overflow. In some embodiments, the first fasteners 160 are located between the first sealing tape 220 and the second sealing tape 220a adjacent to the first sealing tape 220. The first fasteners 160 are located between the second sealing tape 220a and the third sealing tape 220b adjacent to the second sealing tape 220a.

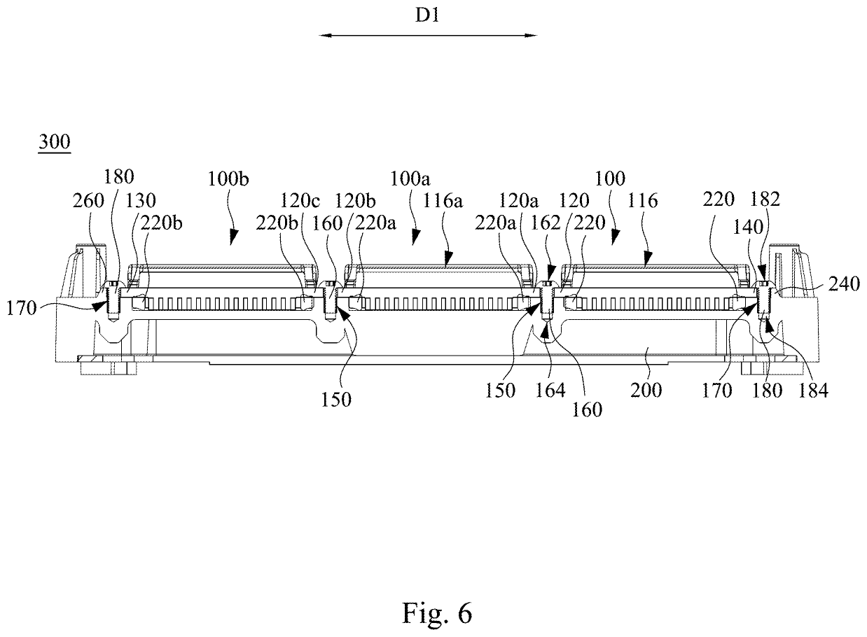

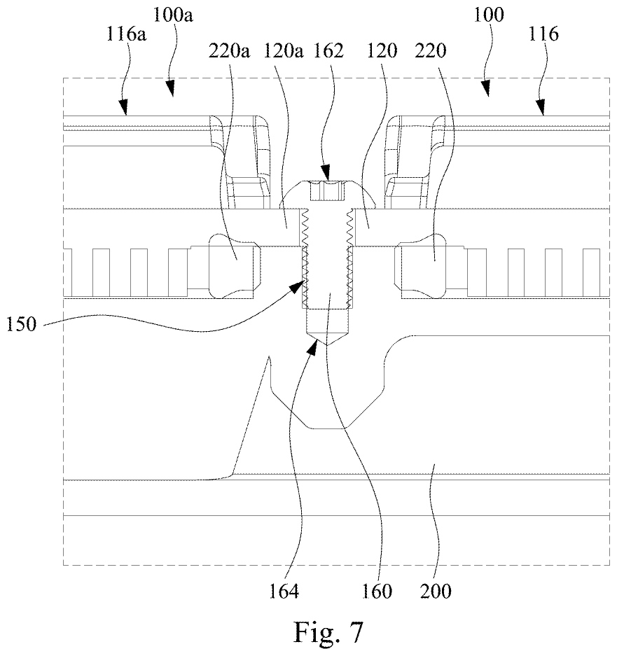

FIG. 6 illustrates a cross-sectional view of the power module 300 of FIG. 3 along a line segment A-A. FIG. 7 illustrates an enlarged view of the first fasteners 160 of FIG. 6. Referring to both FIG. 6 and FIG. 7, Top portions 162 of the first fasteners 160 of the power module 300 are lower than a top portion 116 of the first power device 100 and a top portion 116a of the second power device 100a. Bottom portions 164 of the first fasteners 160 pass through the first inserting holes 150 to be fixed in the housing 200. In addition, the first fasteners 160 of the power module 300 are located between the first sealing tape 220 and the second sealing tape 220a and located between the second sealing tape 220a and the third sealing tape 220b. The first fasteners 160 are directly locked to the first extending portion 120 of the first power device 100, the first extending portion 120a of the second power device 100a and the first extending portion 120c of the third power device 100b, so an average downforce is provided to the first sealing tape 220, the second sealing tape 220a and the third sealing tape 220b, which may avoid uneven pressure on the first sealing tape 220, the second sealing tape 220a and the third sealing tape 220b and may prevent the cooling liquid below the first power device 100, the second power device 100a and the third power device 100b from overflowing.

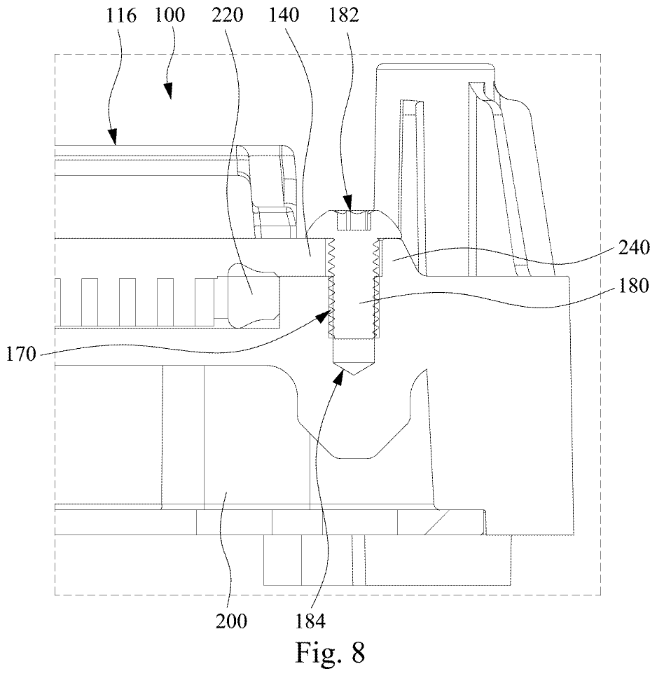

FIG. 8 illustrates an enlarged view of the second fasteners 180 of FIG. 6. Referring to both FIG. 6 and FIG. 8, Top portions 182 of the second fasteners 180 of the power module 300 are lower than the top portion 116 of the first power device 100 and the top portion 116a of the second power device 100a (see FIG. 7). Bottom portions 184 of the second fasteners 180 pass through the second inserting holes 170 to be fixed in the housing 200. In addition, the first protruding rib 240 of the housing 200 of the power module 300 is coplanar with the second extending portion 140 of the first power device 100. The second fasteners 180 of the power module 300 pass through the second inserting holes 170 and are directly locked to the second extending portion 140 of the first power device 100 and the first protruding rib 240 of the housing 200, so an average downforce is provided to the first sealing tape 220, the second sealing tape 220a and the third sealing tape 220b, which may avoid uneven pressure on the first sealing tape 220, the second sealing tape 220a and the third sealing tape 220b and may prevent the cooling liquid below the first power device 100, the second power device 100a and the third power device 100b from overflowing.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A power device, comprising:
a main body portion; and
a first extending portion extending from a first side of the main body portion and having a first curved opening, wherein the first curved opening is used to receive a first fastener, the first fastener passes through the first curved opening to be locked, and the main body portion and the first extending portion are formed in a stepped structure.

2. The power device of claim 1, wherein the first extending portion is elongated, the first extending portion is adjacent to the first side of the main body portion, and the first curved opening is near one end of the first extending portion.

3. The power device of claim 1, wherein the first extending portion is elongated, the first extending portion is adjacent to the first side of the main body portion, and the first curved opening is disposed in a middle of the first extending portion.

4. The power device of claim 1, further comprising:
a second extending portion extending from a second side opposite to the first side of the main body portion, wherein the second extending portion has a second curved opening for receiving a second fastener, the second fastener passes through the second curved opening to be locked, the main body portion and the second extending portion are formed in a stepped structure, the first curved opening and the second curved opening face opposite directions, and the second curved opening of the second extending portion is symmetrically disposed with the first curved opening of the first extending portion.

5. The power device of claim 4, further comprising:
a housing having an accommodating space; and
a sealing tape located in the accommodating space of the housing, wherein the sealing tape is located below the first extending portion and the second extending portion.

6. The power device of claim 5, wherein an inserting hole is formed by the second curved opening of the second extending portion and a curved opening of a first protruding rib of the housing.

7. The power device of claim 6, wherein the housing has a second protruding rib opposite to the first protruding rib, and a curved opening of the second protruding rib corresponds to the first curved opening of the first extending portion.

8. A power module, comprising:
a plurality of first fasteners; and
a plurality of power devices disposed adjacently and locked by the first fasteners, wherein each of the power devices packages a power electronic therein, each of the power devices includes a first extending portion, each of the first extending portions extends from a side of each of the power devices, each of the first extending portions includes at least one first curved opening for receiving one of the first fasteners, two of the first curved openings are disposed to each other and form a first inserting hole, and one of the first fasteners passes through the first inserting hole.

9. The power module of claim 8, wherein the power devices are a first power device and a second power device adjacent to each other, and a top of one of the first fasteners is lower than a top of the first power device and a top of the second power device.

10. The power module of claim 8, further comprising:
a housing carrying the power devices, wherein a bottom of one of the first fasteners is fixed in the housing; and
a second fastener passing through a second inserting hole and having a bottom fixed in the housing, wherein the second inserting hole is located at a second extending portion of one of the power devices.

11. The power module of claim 10, wherein the housing includes a protruding rib, the protruding rib is adjacent to the second extending portion, and a second curved opening of the second extending portion corresponds to a curved opening of the protruding rib to form the second inserting hole, and the second fastener is locked to the second extending portion and the protruding rib of the housing.

12. The power module of claim 11, wherein the protruding rib of the housing is coplanar with the second extending portion.

13. The power module of claim 10, further comprising:
sealing tapes located in accommodating spaces of the housing, respectively, wherein one of the power devices covers one of the accommodating spaces, and the sealing tapes are located below the power devices.

14. The power module of claim 13, wherein the first fasteners are located between adjacent two of the sealing tapes.

15. A power module, comprising:
a housing having two protruding ribs opposite to each other;
a plurality of fasteners fixed in the housing ; and
a plurality of power devices located between the two protruding ribs of the housing, adjacently arranged along a length direction of the housing and disposed in the housing, wherein two of the power devices are adjacent to the two protruding ribs, respectively, each of the power devices includes two extending portions opposite to each other, first inserting holes are formed by curved openings of the extending portions of two adjacent power devices, second inserting holes are formed by curved openings of the extending portions of said two of the power devices and curved openings of the two protruding ribs of the housing, and the power devices are locked by the fasteners through the first inserting holes and the second inserting holes.

16. The power module of claim 15, further comprising:
sealing tapes located in accommodating spaces of the housing, respectively, wherein the power devices cover the accommodating spaces, and the sealing tapes are located below the power devices.

17. The power module of claim 16, wherein the fasteners are located between adjacent two of the sealing tapes.

18. The power module of claim 15, wherein one of the two protruding ribs of the housing is coplanar with one of the extending portions of said two of the power devices.
